(19) United States
(12) Patent Application Publication
(10) Pub. No.: US 2026/0358655 A1
(43) Pub. Date: Nov. 12, 2026

(54) Charging Device For Smart Wearable Device

(71) Applicant: AAC ACOUSTIC TECHNOLOGIES (SHENZHEN) CO., LTD., Shenzhen (CN)

(72) Inventors: Xiuliang Xie, Shenzhen (CN); Qingshan Xu, Shenzhen (CN); Hongyan Tao, Shenzhen (CN)

(21) Appl. No.: 19/295,742

(22) Filed: Aug. 11, 2025

Related U.S. Application Data
(63) Continuation of application No. PCT/CN2025/092992, filed on May 7, 2025.

(51) Int. Cl. G02C 11/00; G02B 27/01; G02C 5/14; G06F 1/16; H01R 13/24; H01R 13/447; H05K 5/06

(52) U.S. Cl. CPC G02C 11/10; G02B 27/0176; G02C 5/14; G06F 1/163; H01R 13/2407; H01R 13/2471; H01R 13/447; H05K 5/061; G02B 2027/0169; G02B 2027/0178; G02C 2200/02

(57) ABSTRACT

The present invention provides a charging device for smart wearable device including a temple and a charging socket. The temple includes a housing, a circuit board, a pair of charging pins, a bracket, and a pair of conductive spring pieces. The housing includes a pair of charging holes for electrically connecting the charging pins to the charging socket. The housing includes a lower wall, a top wall, and a side wall. Each of two sides of the bracket is provided with one elastic arm, and each elastic arm has a locked portion. The side wall of the housing is provided with a protruding clamped portion corresponding to each locked portion. The bracket is fixedly connected with the housing through the locked portions and the clamped portions. The charging device for smart wearable device of the present invention has a stable structure and better durability.

### FIELD OF THE PRESENT INVENTION

The present invention relates to the field of charging technology for smart wearable device, and more particularly, to a charging device for smart wearable device.

### DESCRIPTION OF RELATED ART

With the rapid development of the electronics industry, smart devices with playback functions are also rapidly emerging. The smart devices can play the functions of music playback and phone calls. Such as smart glasses, VR equipment, mobile phones, tablets, etc. Smart glasses generally have a charging structure in its temple to charge the smart glasses, so as to meet the power supply requirements for the normal operation of audio or camera modules in smart glasses.

In the related art, smart glasses are usually charged by placing them in the glasses case using wireless charging or contact points. However, due to the temples being folded firstly and then being placed in the glasses case, there is structural interference between the temples, which makes it difficult for the magnetic charging contacts of the glasses to align with the contacts of the glasses case, making it inconvenient for charging. In another related art, smart glasses can be electrically connected to a charging socket for charging. However, in practical applications, it has been found that after a certain number of uses, the charging structure is easy to loosening, resulting in poor contact and making it difficult to charge normally.

Therefore, it is desired to provide a new charging device for smart wearable device which can overcome the above problems.

### SUMMARY

In view of the above, the embodiments of the present invention provide a new charging device for smart wearable device having a more stable structure and better durability.

The present invention provides a charging device for smart wearable device including a temple and a charging socket for charging the temple. The temple includes a housing having a receiving room, a circuit board received in the receiving room, a pair of charging pins located at an end portion of the housing, a bracket fixedly connected to one end of the circuit board proximal to the end portion of the housing, and a pair of conductive spring pieces, and each conductive spring piece is abutted against between the circuit board and the corresponding charging pin. The housing includes a pair of charging holes for electrically connecting the charging pins to the charging socket. The housing includes a lower wall, a top wall opposite to the lower wall, and a side wall connecting the lower wall and the top wall. Two sides of the bracket are provided with one elastic arm, and each elastic arm has a locked portion. The side wall of the housing is provided with a protruding clamped portion corresponding to each locked portion. The bracket is fixedly connected with the housing through the locked portions and the clamped portions.

As an improvement, the bracket includes a lower surface fixed with the lower wall of the housing, an upper surface opposite to the lower surface, a front surface facing the charging holes, and a pair of side surfaces connecting the lower surface and the upper surface, the circuit board including an extending portion mounted on the lower wall of the housing and a bending portion bending and extending from the extending portion and fixed to the front surface of the bracket, the bracket having at least one through portion penetrating the upper surface and the lower surface, the lower wall of the housing provided with at least one fixing hole extending from the lower wall, the charging device for smart wearable device further including a screw mounted in the through portion and the fixing hole.

As an improvement, the bracket and the circuit board are fixed by glue.

As an improvement, the charging device for smart wearable device further includes a sealing ring closely sleeved on each charging pin.

As an improvement, the charging socket includes a cover, a support member fixed in the cover, a pair of charging terminals fixed in the support member, and a magnet fixed to the support member, the temple including a magnetic member fixed in the housing, and the magnet and the magnetic member attract each other.

As an improvement, an inner surface of the cover is provided with a protrusion portion, and a surface of the support member is provided with a recess portion, the protrusion portion clamped and fixed with the recess portion; or an inner surface of the cover is provided with a recess portion, and a surface of the support member is provided with a protrusion portion, the protrusion portion clamped and fixed with the recess portion.

As an improvement, the front surface is provided with at least one positioning protrusion, and the bending portion of the circuit board is provided with at least one positioning hole corresponding to the positioning protrusion, the positioning protrusion located in the corresponding positioning hole.

As an improvement, the charging device for smart wearable device further includes a pair of circlips located mounted in the housing, each circlip sleeved on the charging pin to fix the charging pin to the housing.

As an improvement, the magnet is fixed to the support member by glue, and the magnetic member is fixed to the housing by glue.

As an improvement, the cover is made of magnetically attractable material.

### BRIEF DESCRIPTION OF THE DRAWINGS

Many aspects of the exemplary embodiments can be better understood with reference to the following drawing. The components in the drawing are not necessarily drawn to scale, the emphasis instead being placed upon clearly illustrating the principles of the present invention. Moreover, in the drawings, like reference numerals designate corresponding parts throughout the several views.

FIG. 1 is an illustrative isometric view of a charging device for smart wearable device in accordance with one embodiment of the present invention.

FIG. 2 is a partially exploded view of the charging device for smart wearable device of FIG. 1.

FIG. 3 is another partially exploded view of the charging device for smart wearable device of FIG. 1.

FIG. 4 is an exploded view of the charging device for smart wearable device of FIG. 1.

FIG. 5 is an illustrative cross-sectional view of the temple taken along line A-A of FIG. 2.

### DETAILED DESCRIPTION OF THE EXEMPLARY EMBODIMENTS

The present invention will hereinafter be described in detail with reference to exemplary embodiments. To make the technical problems to be solved, technical solutions and beneficial effects of the present invention more apparent, the present invention is described in further detail together with the figures and the embodiments. It should be understood the specific embodiments described hereby is only to explain the disclosure, not intended to limit the disclosure.

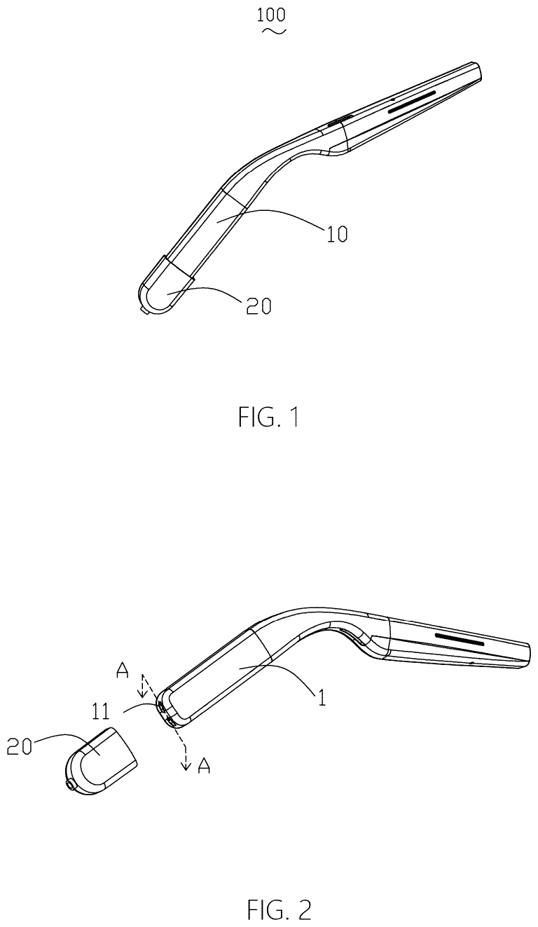

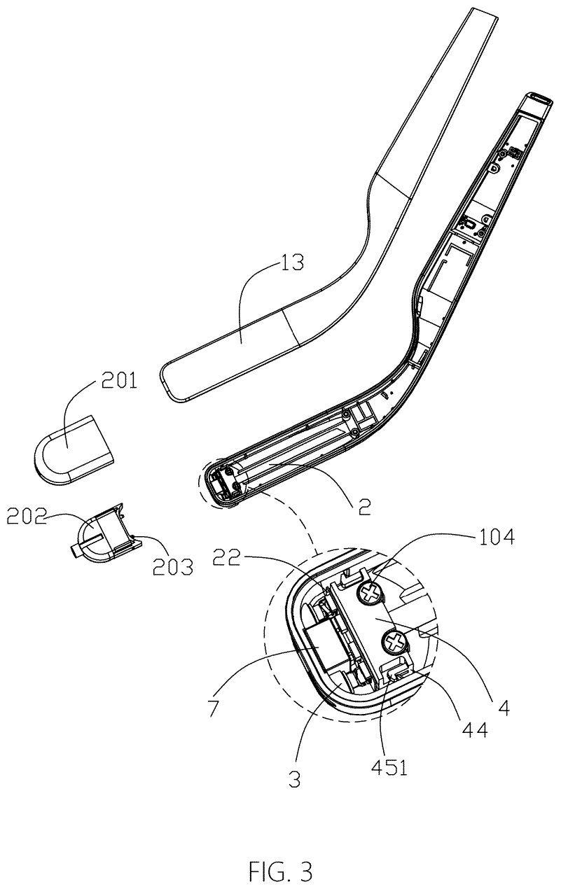

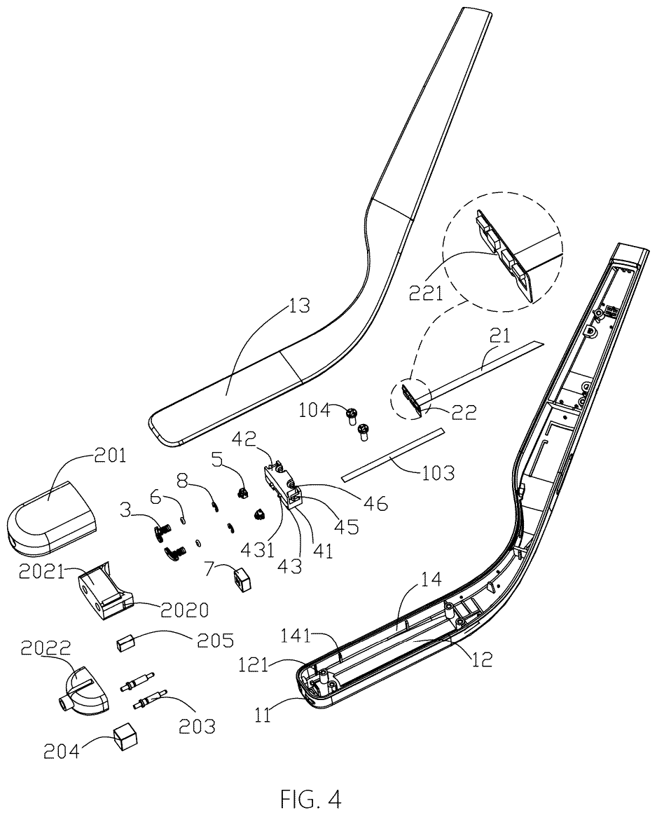

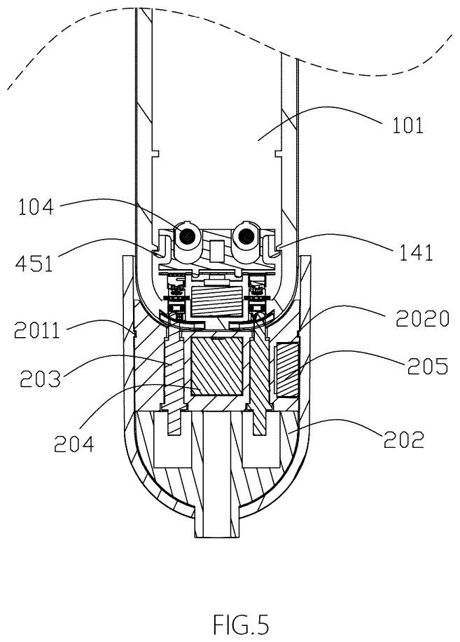

Referring to the FIGS. 1-5, the present invention provides one embodiment of a charging device for smart wearable device 100. The charging device for smart wearable device 100 includes a temple 10 and a charging socket 20 for charging the temple 10. The temples 10 of the charging device for smart wearable device 100 are a pair, and the structures of the pair of temples 10 are symmetrical structures. In order to facilitate charging, the number of the charging sockets 20 is also a pair.

The temple 10 includes a housing 1 having a receiving room 101, a circuit board 2 received in the receiving room 101, a pair of charging pins 3 located at an end portion of the housing 1, a bracket 4 fixedly connected to one end of the circuit board 2 proximal to the end portion of the housing 1, and a pair of conductive spring pieces 5, a sealing ring 6 closely sleeved on each charging pin 3, a magnetic member 7, and a pair of circlips 8. Each conductive spring piece 5 is abutted against between the circuit board 2 and the corresponding charging pin 3.

The housing 1 includes a pair of charging holes 11 located on the end portion of the housing 1 for electrically connecting the charging pins 3 to the charging socket 20. The housing 1 includes a lower wall 12, a top wall 13 opposite to the lower wall 12, and a side wall 14 connecting the lower wall 12 and the top wall 13. The lower wall 12 of the housing 1 is provided with at least one fixing hole 121 extending from the lower wall 12. The side wall 14 of the housing 1 is provided with a protruding clamped portion 141.

The circuit board 2 is secured to the housing 1. In detail, the circuit board 2 is fixed to the housing 1 by glue 103. The circuit board 2 includes an extending portion 21 mounted on the lower wall 12 of the housing 1 and a bending portion 22 bending and extending from the extending portion 21 and fixed to the bracket 4. Electronic components can be installed on the bending portion 22. The bending portion 22 of the circuit board 2 is provided with at least one positioning hole 221. The bracket 4 and the circuit board 2 are fixed by glue. In detail, the bracket 4 is fixed with the bending portion 22 of the circuit board 2 by glue. The charging device for smart wearable device 100 further includes a battery (not shown), and the circuit board 2 is connected to the battery for charging the battery.

The bracket 4 includes a lower surface 41 fixed with the lower wall 12 of the housing 1, an upper surface 42 opposite to the lower surface 41, a front surface 43 facing the charging holes 11, and a pair of side surfaces 44 connecting the lower surface 41 and the upper surface 42. The bending portion 22 of the circuit board 2 is fixed to the front surface 43 of bracket 4. There is a glue gap between the bending portion 22 and the front surface 43 of the bracket 4, and the glue is located in the glue gap to fix the bending portion 22 and the bracket 4. Each of two sides of the bracket 4 is provided with one elastic arm 45, and each elastic arm 45 has a locked portion 451. The bracket 4 is further fixedly connected with the housing 1 through the locked portions 451 and the clamped portions 141. The bracket 4 has at least one through portion 46 penetrating the upper surface 42 and the lower surface 41. The charging device for smart wearable device 100 further includes a screw 104 mounted in the through portion 46 and the fixing hole 121. The charging device for smart wearable device 100 further fixes the bracket 4 to the housing 1 through the screw 104. The front surface 43 of the bracket 4 is provided with at least one positioning protrusion 431 corresponding to the positioning hole 221 of the circuit board 2, and the positioning protrusion 431 locates in the corresponding positioning hole 221 to accurately position the bracket 4 and the circuit board 2.

Therefore, in the charging device for smart wearable device 100 of the present invention, the bracket 4 and the housing 1 are fixed through a structure of snap-fit, the circuit board 2 and the bracket 4 are fixed by glue, and the bracket 4 and the housing 1 are simultaneously fixed by screws 104, thereby stabilizing the structure of the circuit board 2, the bracket 4, and the housing 1. And the durability of the charging device for smart wearable device 100 is better.

The charging pins 3 are a pair, and the charging pins 3 locate in the charging holes 11. The sealing ring 6 is closely sleeved on each charging pin 3 to prevent water vapor or dust from entering the receiving room 101 of the housing 1. The circlips 8 are located in the receiving room 101 of the housing 1 and are sleeved on the corresponding charging pin 3 to fix the charging pin 3 to the housing 1.

The charging socket 20 includes a cover 201, a support member 202 fixed in the cover 201, a pair of charging terminals 203 fixed in the support member 202, and a magnet 204 fixed to the support member 202. The magnet 204 is fixed to the support member 202 by glue. The temple 10 includes the magnetic member 7 fixed in the housing 1 by glue, and the magnet 204 and the magnetic member 7 attract each other, so that when the temple 10 is charged, the temple 10 can be stably connected to the charging socket 20. The numbers of the charging terminals 203 and charging pins 3 are two, and the charging terminals 203 correspond one-to-one with the charging pins 3. The magnet 204 is located between the two charging terminals 203, and the magnetic member 7 is located between the two charging pins 3.

The cover 201 is made of magnetically attractable material. An inner surface of the cover 201 is provided with a protrusion portion 2011, and a surface of the support member 202 is provided with a recess portion 2020. The protrusion portion 2011 is clamped and fixed with the recess portion 2020. Or, in other embodiment, an inner surface of the cover 201 is provided with a recess portion, and a surface of the support member 202 is provided with a protrusion portion. The protrusion portion is clamped and fixed with the recess portion.

The support member 202 includes a first support member 2021 and a second support member 2022 connected to each other, and the charging terminals 203 are inserted into the first support member 2021.

The charging socket 20 also includes a magnetic attraction component 205 located inside the cover 201 and on one side of the charging socket 20. In practical applications, another magnetic attraction component is installed inside another charging socket 20. When the temples do not need to be charged, the two magnetic attraction components attract each other to facilitate the storage of the charging socket.

When the temple 10 is charged, the charging terminals 203 are inserted into the charging pins 3, and at this time, part of the temple 10 is accommodated inside the cover 201.

When assembling the temple 10, installing the sealing ring 6 on each charging pin 3, installing the charging pin 3 on the housing 1 through the circlip 8, bonding the magnetic member 7 to the housing 1 with glue, bonding the circuit board 2 and the bracket 4 together with glue, attaching the conductive spring pieces 5 to the bending portion 22 of the circuit board 2, installing the magnetic member 7 on the housing 1, pushing the circuit board 2 and the bracket 4 into the housing 1 together until the locked portion 451 of the elastic arm 45 on the bracket 4 is fixed to the clamped portion 141 of the housing 1, fixing the bracket 4 and the housing 1 with screws 104, and further using glue 103 to fix the circuit board 2 and the housing 1. At this point, the installation of the temple 10 is completed, and the conductive spring pieces 5 are connected to the charging pins 3 together.

When assembling the charging socket 20, installing the magnet 204 on the first support member 2021 with glue, installing the charging terminals 203 on the first support member 2021 too, bonding the first support member 2021 and the second support member 2022 together, sleeving the cover 201 onto the support member 202 until the protruding portion 2011 and the recessed portion 2020 are fixed by the structure of snap-fit. To ensure installation stability, glue can also be filled in the gap between the cover 201 and the support member 202. At this point, the installation of the charging socket 20 is completed.

Comparing with the related art, the present invention provides a charging device for smart wearable device including a temple and a charging socket for charging the temple. The temple includes a housing having a receiving room, a circuit board received in the receiving room, a pair of charging pins located at an end portion of the housing, a bracket fixedly connected to one end of the circuit board proximal to the end portion of the housing, and a pair of conductive spring pieces, and each conductive spring piece is abutted against between the circuit board and the corresponding charging pin. The housing includes a pair of charging holes for electrically connecting the charging pins to the charging socket. The housing includes a lower wall, a top wall opposite to the lower wall, and a side wall connecting the lower wall and the top wall. Two sides of the bracket are provided with one elastic arm, and each elastic arm has a locked portion. The side wall of the housing is provided with a protruding clamped portion corresponding to each locked portion. The bracket is fixedly connected with the housing through the locked portions and the clamped portions. In the charging device for smart wearable device of present invention, the bracket and the housing are fixed through a structure of snap-fit, the circuit board and the bracket are fixed by glue, and the bracket and the housing are simultaneously fixed by screws, thereby stabilizing the structure of the circuit board, the bracket, and the housing. And the durability of the charging device for smart wearable device 100 is better.

It is to be understood, however, that even though numerous characteristics and advantages of the present exemplary embodiments have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A charging device for smart wearable device, comprising:
a temple, the temple comprising a housing having a receiving room, a circuit board received in the receiving room, a pair of charging pins located at an end portion of the housing, a bracket fixedly connected to one end of the circuit board proximal to the end portion of the housing, and a pair of conductive spring pieces, each conductive spring piece abutted against between the circuit board and the corresponding charging pin; and
a charging socket for charging the temple;
the housing comprising a pair of charging holes for electrically connecting the charging pins to the charging socket, the housing comprising a lower wall, a top wall opposite to the lower wall, and a side wall connecting the lower wall and the top wall, two sides of the bracket provided with one elastic arm, and each elastic arm having a locked portion, the side wall of the housing provided with a protruding clamped portion corresponding to each locked portion, the bracket fixedly connected with the housing through the locked portions and the clamped portions.

2. The charging device for smart wearable device as described in claim 1, wherein the bracket comprises a lower surface fixed with the lower wall of the housing, an upper surface opposite to the lower surface, a front surface facing the charging holes, and a pair of side surfaces connecting the lower surface and the upper surface, the circuit board comprising an extending portion mounted on the lower wall of the housing and a bending portion bending and extending from the extending portion and fixed to the front surface of the bracket, the bracket having at least one through portion penetrating the upper surface and the lower surface, the lower wall of the housing provided with at least one fixing hole extending from the lower wall, the charging device for smart wearable device further comprising a screw mounted in the through portion and the fixing hole.

3. The charging device for smart wearable device as described in claim 1, wherein the bracket and the circuit board are fixed by glue.

4. The charging device for smart wearable device as described in claim 1, wherein the charging device for smart wearable device further comprises a sealing ring closely sleeved on each charging pin.

5. The charging device for smart wearable device as described in claim 1, wherein the charging socket comprises a cover, a support member fixed in the cover, a pair of charging terminals fixed in the support member, and a magnet fixed to the support member, the temple comprising a magnetic member fixed in the housing, and the magnet and the magnetic member attract each other.

6. The charging device for smart wearable device as described in claim 5, wherein an inner surface of the cover is provided with a protrusion portion, and a surface of the support member is provided with a recess portion, the protrusion portion clamped and fixed with the recess portion;
or, an inner surface of the cover is provided with a recess portion, and a surface of the support member is provided with a protrusion portion, the protrusion portion clamped and fixed with the recess portion.

7. The charging device for smart wearable device as described in claim 2, wherein the front surface is provided with at least one positioning protrusion, and the bending portion of the circuit board is provided with at least one positioning hole corresponding to the positioning protrusion, the positioning protrusion located in the corresponding positioning hole.

8. The charging device for smart wearable device as described in claim 1, wherein the charging device for smart wearable device further comprises a pair of circlips mounted in the receiving room of the housing, each circlip sleeved on the corresponding charging pin to fix the charging pin to the housing.

9. The charging device for smart wearable device as described in claim 5, wherein the magnet is fixed to the support member by glue, and the magnetic member is fixed to the housing by glue.

10. The charging device for smart wearable device as described in claim 5, wherein the cover is made of magnetically attractable material.
